(19) United States
(12) Patent Application Publication
(10) Pub. No.: US 2025/0300027 A1
(43) Pub. Date: Sep. 25, 2025

(54) WAFER CAP ATTACHMENT FOR SEMICONDUCTOR DEVICES

(71) Applicant: TEXAS INSTRUMENTS INCORPORATED, DALLAS, TX (US)

(72) Inventors: Jeff Jerard CANDA, SAN FERNANDO (PH); Jomari AUSTRIA, MALABON CITY (PH); Lorraine QUIJANO, ANGELES (PH)

(21) Appl. No.: 18/610,627

(22) Filed: Mar. 20, 2024

(51) Int. Cl. H01L 23/10; H01L 21/56; H01L 23/00; H01L 23/31; H01L 23/495

(52) U.S. Cl. CPC H01L 23/10; H01L 21/56; H01L 23/3107; H01L 23/49503; H01L 24/83; H01L 2224/83801

(57) ABSTRACT

An example apparatus includes a substrate having opposing first and second surfaces. The apparatus also includes an on-substrate device on the first surface of the substrate and a wafer cap on the first surface of the substrate over the on-substrate device. A peripheral ring layer of a fusible alloy is configured to hermetically seal the wafer cap to the first surface of the substrate around the on-substrate device.

### BACKGROUND

Wafer-level packaging is a packaging technique often used to isolate circuits and components from the package environment. For example, wafer-level packaging can be used to form microelectromechanical systems (MEMS) or bulk acoustic wave resonators, such as including sensors, accelerometers, optical sensors, or microactuators. As an example, wafer-level packaging can be implemented to affix a wafer cap to a substrate over a MEMS or BAW resonator, which can be formed on the substrate, and the devices are singulated and packaged.

### SUMMARY

One described example relates to an apparatus that includes a substrate having opposing first and second surfaces. The apparatus also includes an on-substrate device on the first surface of the substrate and a wafer cap on the first surface of the substrate over the on-substrate device. A peripheral ring layer of a fusible alloy is configured to hermetically seal the wafer cap to the first surface of the substrate around the on-substrate device.

Another described example provides a method of making an apparatus. The method can include providing a substrate that includes an on-substrate device on a first surface of the substrate. The method can also include placing a wafer cap on the first surface of the substrate over the on-substrate device, in which the wafer cap includes a continuous ring of a fusible alloy on a respective surface of the wafer cap, and the ring of the fusible alloy surrounds the on-substrate device. The method can also include reflowing the fusible alloy to bond the respective surface of the wafer cap to the first surface of the substrate and, after cooling, seal the wafer cap around the on-substrate device.

Yet another described example provides a method that includes forming a plurality of instances of a continuous ring of die attach material at respective locations distributed across a first surface of a silicon substrate. Adjacent pairs of the instances of the continuous ring are spaced apart from each other by an area of on the first surface that includes a portion of a saw street that extends across the substrate between respective adjacent pairs of the instances of the continuous ring. The method can also include sawing through respective saw streets of the substrate to singulate wafer caps from the substrate, in which each of the singulated wafer caps includes a respective instance of the continuous ring of die attach material on the first surface thereof. In an example, the sawing is performed using a mechanical saw.

### BRIEF DESCRIPTION OF THE DRAWINGS

FIG. 1 is a flow diagram illustrating an example method for attaching a wafer cap to a semiconductor device.

FIGS. 2A, 2B, 2C, 2D, 2E, 2F, 2G, and 2H are cross-sectional views of a semiconductor device at various stages of the method of FIG. 1.

FIG. 3 is a side sectional view illustrating another example wafer cap attachment for a semiconductor device.

FIG. 4 is a side sectional view illustrating yet another example wafer cap attachment for a semiconductor device.

FIG. 5 is a side sectional view illustrating still another example wafer cap attachment for a semiconductor device.

FIG. 6 is a flow diagram illustrating another example method for attaching a wafer cap to a semiconductor device.

FIGS. 7A and 7B are plan views illustrating an example wafer cap being attached to a semiconductor device.

FIG. 8 is an isometric view illustrating an example semiconductor device that includes a wafer cap attached to a die.

FIG. 9 is a side view illustrating the example semiconductor device of FIG. 8 encapsulated in a mold compound.

### DETAILED DESCRIPTION

This description relates to an apparatus and method of attaching a wafer cap for semiconductor devices.

In an example, an apparatus includes a substrate (e.g., a semiconductor die) having opposing first and second surfaces with an on-substrate (e.g., on-die) device on the first surface of the substrate. A wafer cap can be mounted on the first surface of the substrate over the on-substrate device by a peripheral ring layer of a fusible alloy (e.g., a solder material), which is configured to space the cap from and hermetically seal the wafer cap to the first surface of the substrate around the on-substrate device. In some example embodiments, the on-substrate device is microelectromechanical system (MEMS) device, a bulk acoustic wave (BAW) device (e.g., a BAW resonator or BAW sensor), a transducer device, or another type of device. The on-substrate device can include a thin film piezoelectric material formed on the substrate, such as silicon or another type of substrate (e.g., ceramic, sapphire or glass).

As a further example, the wafer cap can be formed from a semiconductor substrate (e.g., a semiconductor wafer of silicon) in a wafer-level packaging process. In this example, a plurality of instances of a continuous ring of a die-attach material (DAM), such as a fusible alloy or other DAM (e.g., an adhesive, such as an epoxy material), can be formed at respective locations distributed across a respective surface of the semiconductor substrate. Respective wafer caps can be singulated from the semiconductor substrate, such as by mechanical sawing through saw streets between the wafer caps. A given one of the singulated wafer caps can be placed on a first surface of a second substrate (e.g., a semiconductor die) that includes an on-substrate device on the first surface thereof. The placement of the wafer cap can be implemented as part of a package level die-attach process, such that the ring of the die-attach material surrounds the on-substrate device. In example embodiments, in the ring of DAM is a fusible alloy, the fusible alloy can be heated to reflow and bond the respective surface of the wafer cap to the first surface of the second substrate and, after cooling, seal the wafer cap around the MEMS device.

The wafer cap attachment described herein provides an effective technique that can be used to protect the on-substrate device (e.g., a BAW or other device) from external package stress when the device is encapsulated in mold compound. Because the die attach is performed at the die-level, as contrasted to wafer-level processes, the approach described herein can provide a simpler process flow because a complex plasma etch process is not required. The simpler process flow can also reduce the overall processing cost for the on-substrate devices as compared to typically more expensive wafer-level processes.

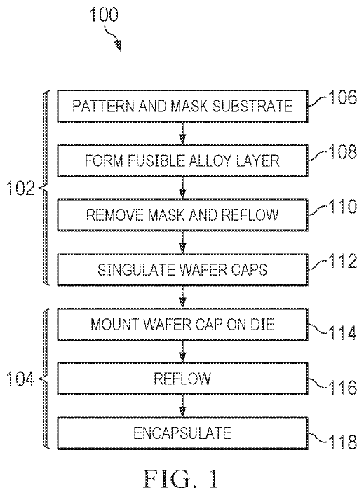

FIG. 1 is a flow diagram illustrating an example method 100, which includes two parts: a first part 102 for forming wafer caps, and a second part 104 for attaching a wafer cap to a semiconductor device. Each part 102, 104 of the method 100 can be implemented separately or in combination. As described herein, the first part 102 can be implemented as part of a wafer-level process and the second part 104 can be implemented as part of a die-level packaging process.

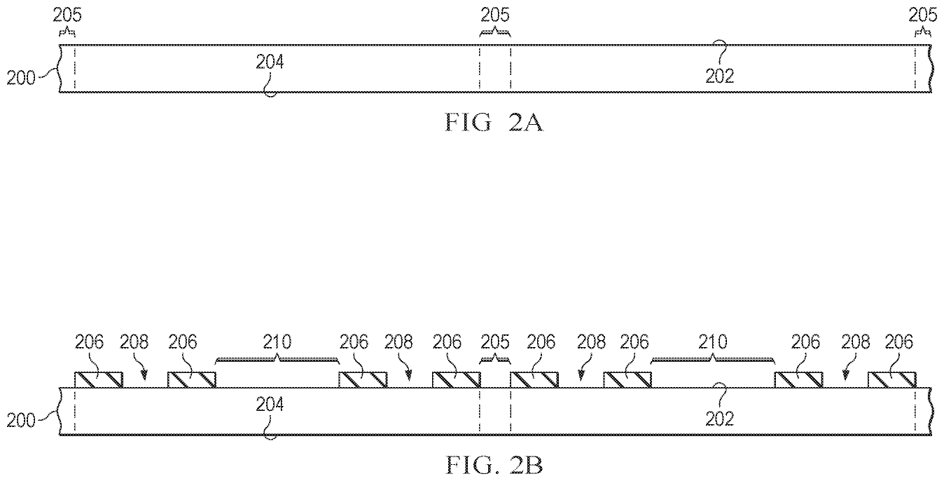

At 106, the method 100 includes patterning and masking a substrate, such as a semiconductor substrate (e.g., a silicon wafer). For example, FIG. 2A illustrates a side sectional view of part of an example semiconductor substrate 200 having opposing surfaces 202 and 204. The substrate 200 can include an arrangement of saw streets 205 extending across the substrate between adjacent areas that are being used to form instances of a wafer cap.

FIG. 2B illustrates a supporting layer 206 formed on the surface 202. For example, the supporting layer 206 is formed of a polymer material (e.g., a polyimide) applied to the surface 202. The supporting layer 206 extends from the surface 202 to terminate in a top surface thereof that is spaced from the surface 202 to define a thickness of the supporting layer 206. The supporting layer 206 can be patterned and etched to form respective channels (e.g., openings) 208 in the supporting layer. In an example embodiment, each respective channel 208 is arranged and configured to provide a continuous channel surrounding an area 210 constituting a central portion of a respective cap body portion. An opening can also be formed in the supporting layer over the saw streets 205, such as to facilitate wafer cap singulation. In a plan view (e.g., looking down on the structure of FIG. 2B), each of the channels 208 on the substrate 200 can have the shape of a ring, which can have as a circular, rectangular or other ring shape. In other example embodiments, the supporting layer 206 may be omitted to reduce the overall cost.

As shown in FIG. 2C, a mask layer 212 is applied over the surface 202 of the substrate 200. In examples that include the supporting layer 206, the mask layer 212 can be applied over the supporting layer, as shown in FIG. 2C. For example, the mask layer can be a photoresist material layer (e.g., a photolithographic mask) that is patterned to expose openings 214 at locations overlying the respective channels 208. Thus, the openings in the mask layer 212 can have ring shapes corresponding to the respective channels 208. Accordingly, the openings 214 likewise can be ring-shaped surrounding the area 210.

Returning to FIG. 1, at 108, the method 100 includes forming a fusible alloy layer. For example, FIG. 2D illustrates a fusible alloy layer 216 formed in the openings 214 of the mask layer 212. The fusible alloy layer 216 can be a solder material, such as tin-silver (SnAg), which can be applied through a plating process. Other fusible alloy materials in solid or paste form (e.g., tin-silver-copper, tin-lead, and the like) can be used in other examples and be applied to the surface 202 by respective processes depending on the type of fusible alloy material.

At 110, the method includes removing the mask and reflowing the fusible alloy. For example, FIG. 2E illustrates the fusible alloy on surface 202 being reflowed (e.g., by heating), shown at 218. For example, the fusible alloy on the surface 202 is heated by passing the assembly through a reflow oven, such as under an infrared lamp. The reflowed fusible alloy is then cooled to provide respective pillars 220, such as in the form of continuous rings of the fusible alloy, around the area 210 of the wafer cap. In example embodiments that include the supporting layer, the portions of the layer 206 along opposing sides of the channel 208, the supporting layer stabilizes the fusible alloy as well as helps to form curved (e.g., ball-shaped) outer surfaces of the fusible alloy pillars 220, as shown in FIG. 2E.

At 112, a plurality of wafer caps are singulated from the substrate. For example, FIG. 2F schematically illustrates a mechanical saw 222 cutting through the saw street 205 to provide an adjacent pair of wafer caps 224. The mechanical sawing to singulate wafer caps 224 from the substrate is more simple and cost effective than existing approaches that use plasma etching. As described herein, the surface 202 of each wafer cap 224 can include a ring-shaped pillar of a fusible alloy along a periphery of the surface 202. The formation of the wafer caps 224 can be the end of the first part 102 of the method 100. The wafer caps 224 can be packaged or otherwise prepared for attachment to respective dies, as described herein. In some examples, each wafer cap has the same size, such as a rectangle of 200 μm by 200 μm, 400 μm by 400 μm, or larger sizes, which can depend on the size of the substrate (e.g., die) to which the wafer caps are being attached.

The second part 104 of the method 100 relates to attachment and packaging. At 114, a respective wafer cap is mounted on a die. For example, FIG. 2G illustrates the wafer cap 224 being mounted on a die 228. The wafer cap 224 can be picked up and inverted (e.g., flipped) from the orientation shown in FIG. 2F and placed in the direction, shown by arrow 230, onto the die 228. The handling of the wafer cap 224 can be implemented during packaging processes using an attachment method and equipment that is the same or similar to that used for attaching a flip-chip die to a substrate, such as to another die or leadframe. For example, as shown in FIG. 2F, the wafer cap 224 is inverted and the fusible alloy 220, which extends along the periphery of the wafer cap 224, is aligned with and contacts a corresponding metal layer 232 on a surface 234 of the die 228. The metal layer 232 can be a ring (e.g., rectangular or circular ring) of metal spaced apart from and surrounding an on-substrate (e.g., on-die) device 236. In one example embodiment, the on-substrate device 236 is a bulk acoustic wave (BAW) device, such as a BAW resonator or BAW sensor. In other examples, the on-substrate device is a MEMS device or other device that can be formed on a die and might be adversely affected by the effects of encapsulation. The ring of metal layer 232 can be copper or another metal (e.g., aluminum or gold), which can be applied to the wafer surface 234 during back-end-of-line processing.

At 116, the method 100 includes reflowing the fusible alloy to bond the wafer cap to the die. For example, FIG. 2H illustrates the fusible alloy 220 on surface 202 being reflowed, shown at 218, to provide an assembly 238 that includes the wafer cap 224 bonded to the die 228. For example, the reflow can be performed by passing the assembly (wafer cap 224 on the die 228) through a reflow oven so the fusible alloy enters a molten state between the wafer cap 224 and die 228, and then cooled to form a bond between the wafer cap 224 and the die 228. The reflow of the continuous ring of fusible alloy at 116 followed by cooling further can form a hermetic seal between the wafer cap 224 and the die 228 around the on-substrate device (e.g., a BAW or other device) 236. In example embodiments where the hermetic seal is not required, the fusible alloy 220 may not be configured and arranged in a continuous ring, but instead can be formed of spaced apart pillars. Such spaced apart pillars can be at opposing edges of the central portion 210 of the cap or be distributed (e.g., as bumps) around the periphery of the central portion. The bond provided by the fusible alloy 220 can also be configured to space the surface 202 of the wafer cap 224 a distance, shown at 240, from the adjacent surface 234 of the die 228. The distance 240 can vary depending on the material of the fusible alloy 220 and the construction of the wafer cap 224. As an example, the distance 240 is greater than approximately 10 μm, such as at least 20 μm, at least 30 μm, or more. The distance 240 of greater than approximately 10 μm helps to reduce (or prevent) mechanical stress on the on-substrate device 236 when the assembly is encapsulated in a mold compound.

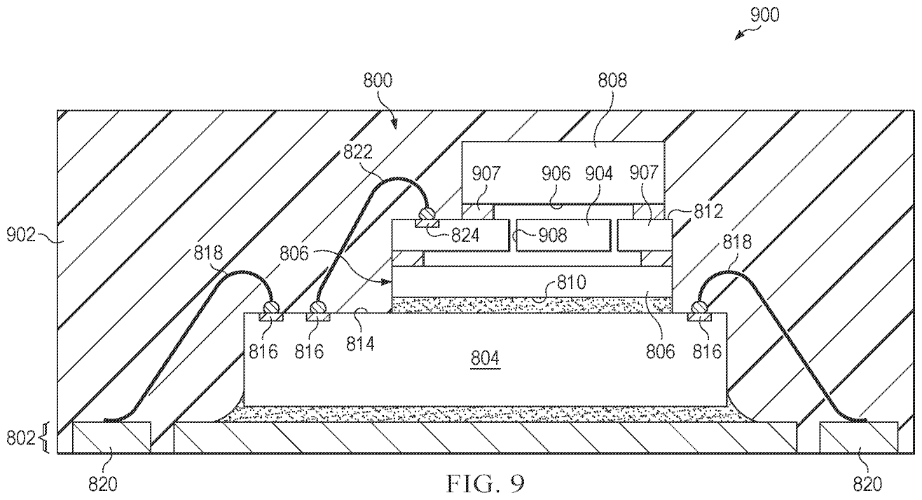

At 118, the method 100 includes encapsulating the assembly to form a packaged semiconductor device. As a further example, the die 228 includes a second side 232 opposite the surface 234 to which the wafer cap is attached, and the second side of the die is attached to a leadframe or to another die (e.g., in a stacked die configuration). The die can be attached to the leadframe or another die by a DAM. The leadframe can include leads or be leadless, which can depend on the type of package being formed. The die, the wafer cap, and at least a portion of the leadframe (or other die) can then be encapsulated within a mold compound (see, e.g., packaged device 900 of FIG. 9). The mold compound can be formed of one or more insulating materials, such as an organic resin (e.g., epoxy), inorganic resins, and/or other suitable materials.

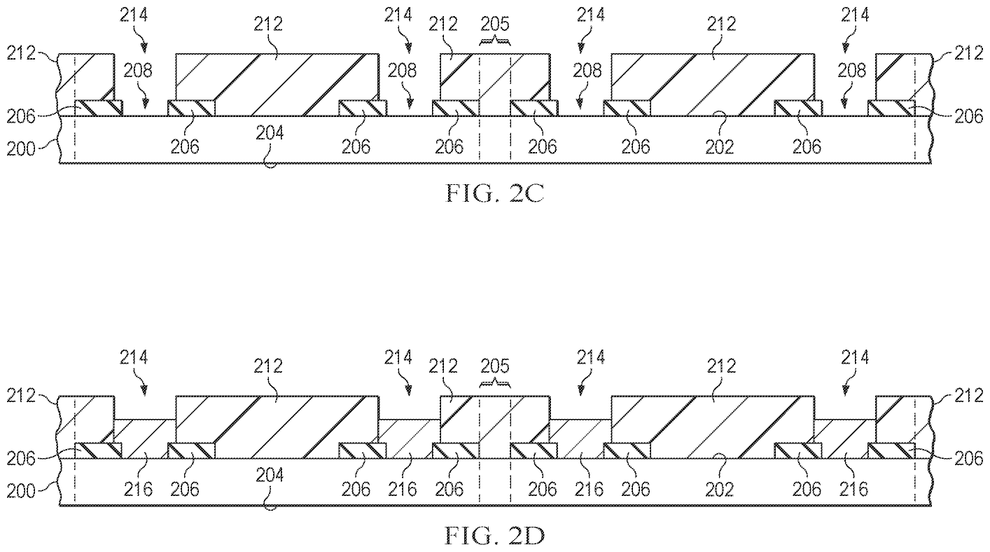

FIGS. 3, 4, and 5 depict some other example embodiments of wafer cap and die assemblies that can be provided. Each of these example assemblies is interchangeable with the assembly 238, and thus can be mounted to a lead frame or to one or more other die (e.g., in a stacked configuration to form an assembly. The assembly is then is encapsulated in a mold compound to form a packaged semiconductor device, as described herein.

FIG. 3 illustrates an example assembly 300 that includes a wafer cap 302 bonded to a substrate (e.g., a die) 304 by a fusible alloy 305. The assembly 300 is similar to the example assembly 238 of FIG. 2H, except a supporting layer 306, which is on a surface 308 of cap substrate 310 extends across a central wafer cap area 312 inwardly from a ring-shaped channel 314. The substrate 304 includes an on-substrate device 316 on a surface 318 of the substrate, such as a BAW or other on-substrate device described herein. A metal layer 320 can also be formed on the surface 318 to provide a bonding pad to which the fusible alloy 305 can bond (e.g., during a reflow process). In some examples, the metal layer 320 and fusible alloy 305 are arranged and configured as coextensive rings to seal around the on-substrate device 316.

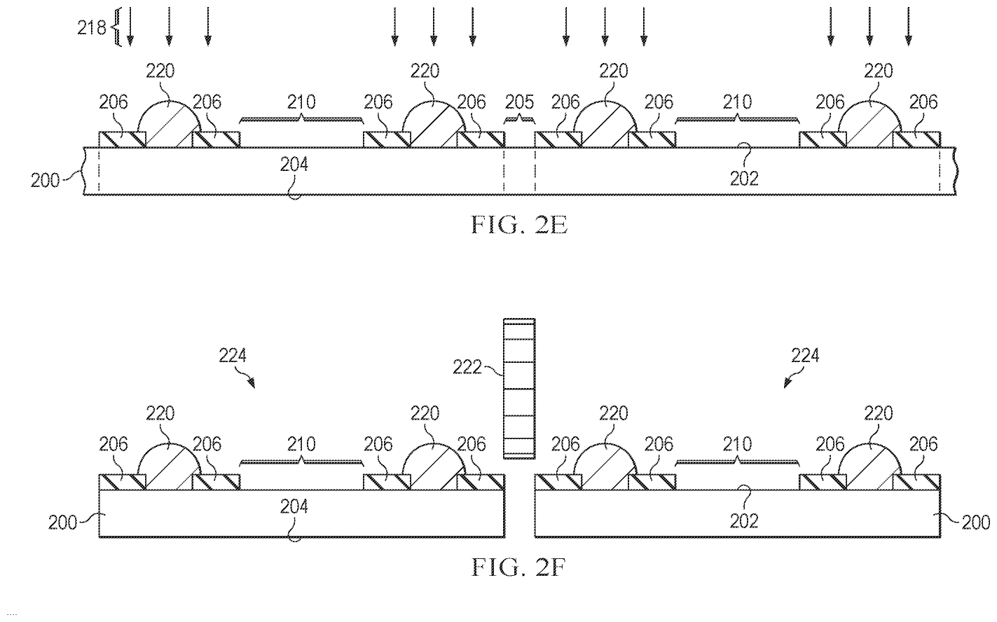

FIG. 4 illustrates another example assembly 400 that includes a wafer cap 402 bonded to a substrate (e.g., a die) 404 by a fusible alloy 406. In the example of FIG. 4, the wafer cap 402 includes a wall structure 408 of a metal material (e.g., copper, gold, nickel or the like) between the fusible alloy 406 and a surface 410 of the cap substrate 412. The wall structure 408 can extend a distance from the surface 410 to terminate in a distal end thereof on which the fusible alloy can be applied (e.g., by plating). The fusible alloy 406 can be formed on the distal end of the wall structure 408 (e.g., at 108) during fabrication of the wafer cap 402. The substrate 404 includes an on-substrate device 414 on a surface 416 of the substrate, such as a BAW or other on-substrate device described herein. A metal layer 418 can also be formed on the surface 416 to provide a bonding pad to which the fusible alloy 405 can bond (e.g., during a reflow process). In some examples, the wall structure 408, the metal layer 418 and fusible alloy 405 are arranged and configured as mating coextensive and continuous rings to form a seal around the on-substrate device 414.

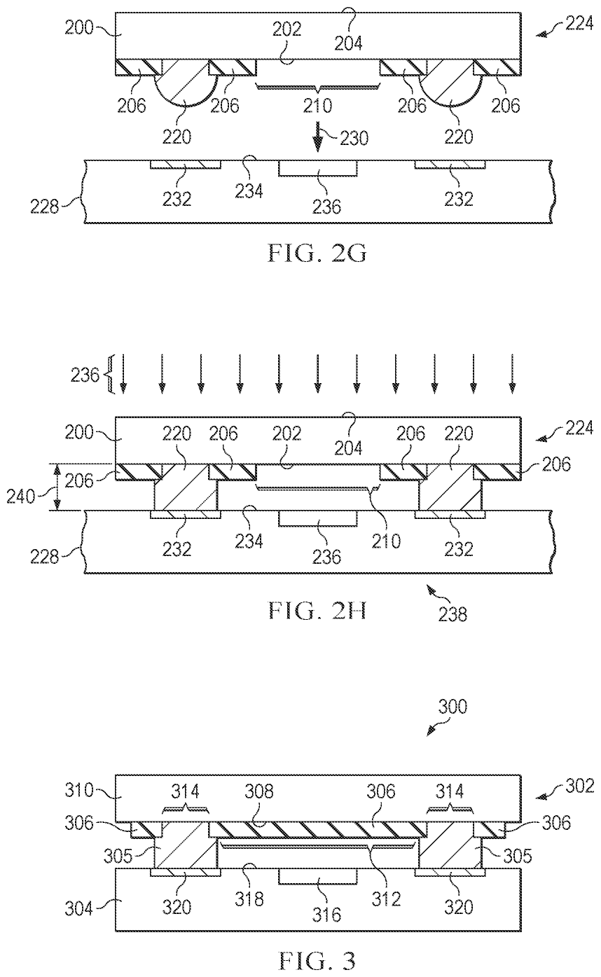

FIG. 5 illustrates another example assembly 500, which can be understood as a combination of the example embodiments of FIGS. 3 and 4. The example assembly 500 includes a wafer cap 502 having a substrate 503 that is bonded to a substrate (e.g., a die) 504 by a fusible alloy 506. In the example of FIG. 5, the wafer cap 502 includes a wall structure 508 of a metal material (e.g., copper, gold, nickel or the like) within a channel 510 of a supporting layer 512 of material (e.g., a polymer), which are on a surface 514 of the substrate 503. The supporting layer 512 can extend across a central area of the wafer cap 502, such as shown in FIG. 3, and provide additional support for the wall structure 508, which extends outwardly from the surface 514 of the substrate 503. The wall structure 508 can extend a distance from the surface 514 to terminate in a distal end thereof on which the fusible alloy 506 can be applied (e.g., by plating or other methods). The fusible alloy 506 can be formed on the distal end of the wall structure 508 (e.g., at 108) during fabrication of the wafer cap 502, such as by plating or another application process. The substrate 504 includes an on-substrate device 516 on a surface 518 of the substrate, such as a BAW or other on-substrate device described herein. A metal layer 520 can also be formed on the surface 518 to provide a bonding pad to which the fusible alloy 506 can bond (e.g., during a reflow process). In some examples, the wall structure 508, the channel 510, the metal layer 518 and fusible alloy 505 are arranged and configured as coextensive and continuous rings to form a seal around the on-substrate device 514.

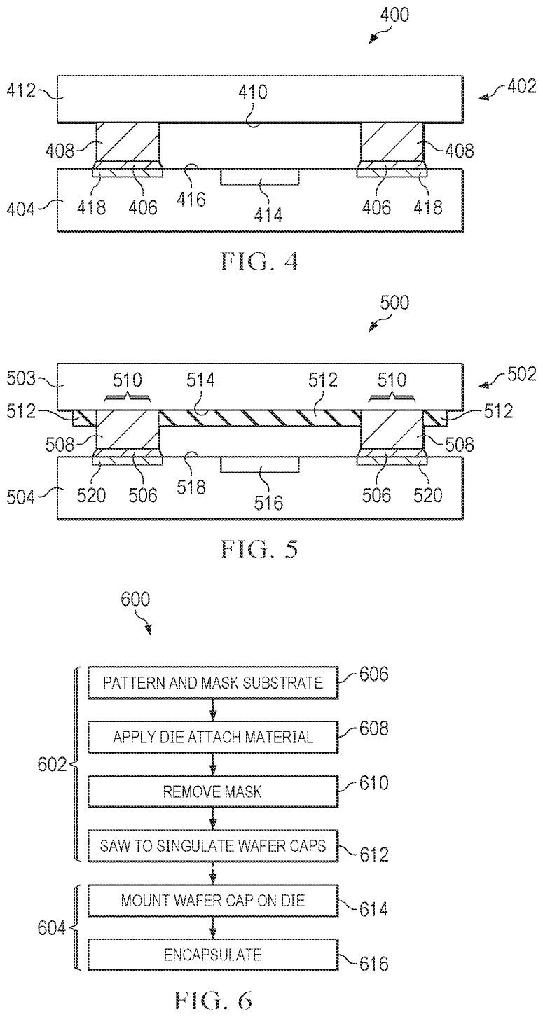

FIG. 6 is a flow diagram illustrating another example method 600, which includes two parts: a first part 602 for forming wafer caps, and a second part 604 for forming a packaged semiconductor device. Each part 602, 604 of the method 600 can be implemented separately or in combination. As described herein, similar to the example of FIG. 1, the first part 602 can be implemented as part of a wafer-level process and the second part 604 can be implemented as part of a die-level packaging process.

At 606, the method 600 includes patterning and masking a substrate, such as a semiconductor substrate (e.g., a silicon wafer). A patterned mask layer can be formed from a photoresist material (e.g., a photolithographic mask) that is deposited and patterned on a surface of the substrate to provide openings at locations corresponding to the respective channels distributed across the surface of the substrate. For example, the channels can form continuous rings in the mask layer.

At 608, the method includes applying a DAM to the surface of the substrate. The DAM can have high mechanical strength adapted to securely hold the wafer cap in place. The DAM can be applied in the channels formed at 606, such as to provide respective rings of the DAM distributed across the surface of the substrate. In the example of FIG. 6, a variety of materials can be used as DAMs, including ceramic materials, such as silver-filled glass, or polymers like epoxy resins filled with silver particles are another popular choice, especially for lower-cost applications. At 610, the mask can be removed after the DAM has been applied at 608.

At 612, the method 600 includes sawing the substrate to singulate a plurality of wafer caps from the substrate. For example, a mechanical saw 222 is used to cut through saw streets extending through the substrate between respective wafer caps. The mechanical sawing to singulate wafer caps from the substrate is more simple and cost effective than existing approaches that use plasma etching. As described herein, each wafer cap thus can include DAM in the form ring-shaped pillar along a periphery of the substrate surface. The formation of the wafer caps responsive to singulating at 612 can be the end of the first part 602 of the method 600.

The second part 604 of the method 600 relates to cap attachment and packaging. At 614, a respective wafer cap is mounted on a die. For example, the wafer cap 224 can be picked up and inverted (e.g., flipped) from the orientation and placed in the direction. The handling of the wafer cap can be implemented during packaging processes using an attachment method and equipment that is the same or similar to that used for attaching a flip-chip device on a substrate, such as another die or leadframe. During attachment of the wafer cap, the DAM is aligned with and contacts a corresponding surface of the die surrounding an on-substrate device (e.g., a BAW device, a MEMS device, or other on-substrate device). The DAM is adapted (e.g., has material properties to bond the wafer cap to the die surface, which can include forming a hermetic seal surrounding the on-substrate device.

At 616, the method 600 includes encapsulating the assembly to form a packaged semiconductor device. As a further example, the die includes a second side opposite the side to which the wafer cap is attached, and the second side of the die is attached to a leadframe. The die can be attached to the leadframe by a DAM. The leadframe can include leads or be leadless, which can depend on the type of package being formed. The die, the wafer cap, and at least a portion of the leadframe can then be encapsulated within a mold compound (see, e.g., packaged semiconductor device 900 of FIG. 9). The mold compound can be formed of one or more insulating materials, such as an organic resin (e.g., epoxy), inorganic resins, and/or other suitable materials.

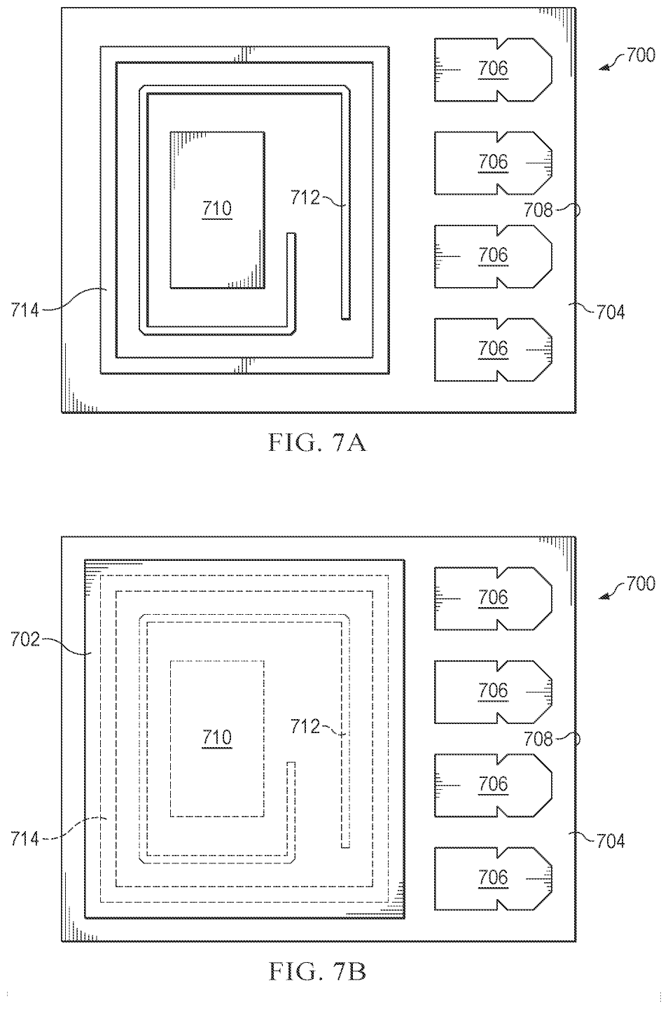

FIGS. 7A and 7B are plan views of a substrate 700 (e.g., substrate 228, 304, 404, or 504) before and after attachment of a wafer cap 702 to the substrate, respectively. The substrate 700 can be a singulated semiconductor die or IC chip, which was formed on a wafer and singulated. The substrate 700 has a surface (e.g., a top surface) 704. In the example of FIGS. 7A and 7B, the substrate 700 includes an arrangement of bond pads 706, such as arranged in a linear array on the surface 704 adjacent a side edge 708 of the substrate. The bond pads 706 can be provided in any arrangement and distribution according to size constraints and application requirements. The substrate 700 also includes an on-substrate device 710 on the surface 704 spaced laterally from the bond pads. The on-substrate device can be a BAW, MEMS or other device. In some examples, the on-substrate device is surrounded by a trench 712 that extends from the surface 704 into the substrate to a bottom that is spaced apart from an opposite surface of the substrate. In this way, the region of the die where the on-substrate device 710 resides defines a platform region configured to support the on-substrate device. The trench 712 thus is configured to provide isolation between the on-substrate device and other circuitry that may be implemented on the substrate 700. The substrate 700 can also include a ring 714 of a metal material (e.g., copper or other metal) on the surface 704 spaced outwardly from and surrounding the trench 712 and the on-substrate device 710.

The wafer cap 702 can be placed over the on-substrate device 710 and bonded to the surface 704 of the substrate 700. For example, a side of the wafer cap 702 facing the surface 704 includes a ring-shaped layer of a DAM (not shown, but see, e.g., DAM materials 220, 305, 406, 506) that aligns spatially and is coextensive with the ring 714. The ring-shaped layer is configured to bond the wafer cap to the substrate 700 and form a seal around the on-substrate device 710. In examples where the DAM is a fusible alloy (e.g., solder, such as tin-silver or other material), the assembly can be heated in a reflow process (e.g., as described at 116 of FIG. 1) to cause the fusible alloy to a molten state and then cooled to form the bond between the wafer cap 702 and substrate 700. As described herein, the bond can provide a hermetic seal around the on-substrate device 710.

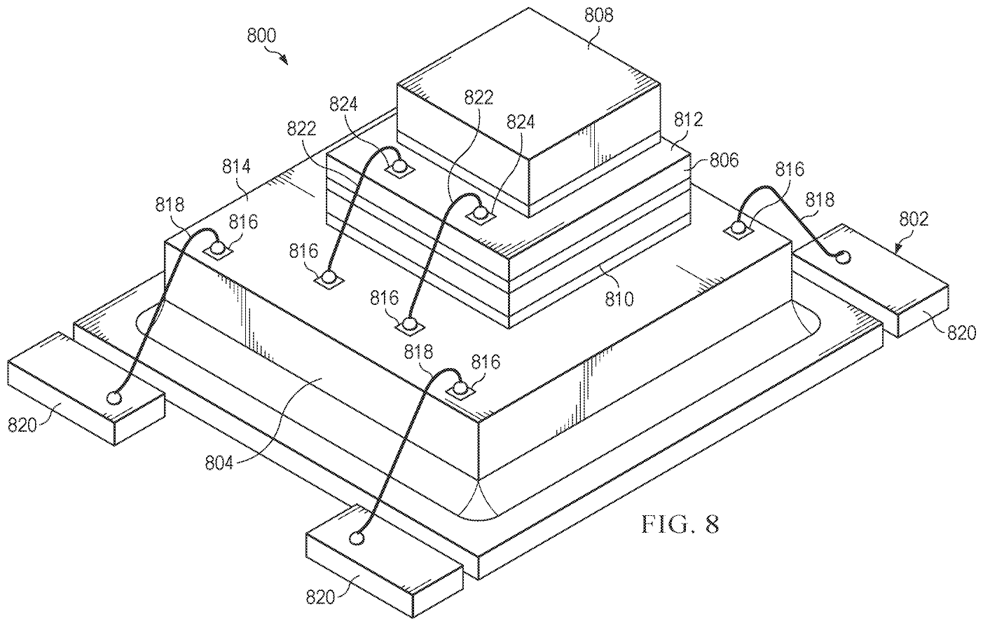

FIG. 8 is an isometric view illustrating an example semiconductor device 800 prior to encapsulation. The semiconductor device 800 in FIG. 8 is a multi-die device that includes a leadframe 802, a first die 804, a second die 806 and a wafer cap 808. In the example of FIG. 8, the first die 804 (e.g., a base die) is mounted to a die-attach area (e.g., a pad) of the leadframe 802, such as by a DAM between the leadframe and the first die. The second die 806 has opposing surfaces 810 and 812, in which a first surface 810 is coupled to a surface (e.g., top surface) 814 of the first die 804, such as by a DAM between the second die and a die-attach pad or region on the surface of the first die. The surface 814 of the first die 804 includes bond pads 816 at respective locations. In the example of FIG. 8, first wire bonds 818 are coupled between some of the bond pads 816 of the first die 804 and respective leads 820 on the leadframe 802. Second wire bonds 822 are coupled between another portion of the bond pads 816 of the first die 804 and bond pads 824 on the surface 812 of the second die 806. There can be any number and arrangement of leads, bond pads and bond wires to make the necessary connections to enable the semiconductor device to function according to application and design expectations.

As a further example, the second die 806 includes an on-substrate device (a BAW device—not shown in FIG. 8 but see, e.g., FIGS. 2G-5) on the second surface 812 of the second die. The wafer cap 808 is mounted on the second surface 812 of the second die in a position overlying the on-substrate device. As described herein, the wafer cap 808 can include a peripheral ring layer of a DAM (e.g., a fusible alloy or other DAM) configured to seal the wafer cap 808 to the surface 812 of the second die 806 in a position that is spaced apart from and surrounding the on-substrate device.

FIG. 9 is a side view of the example semiconductor device 800 encapsulated by a mold compound 902 to provide a packaged semiconductor device 900. In the example of FIG. 9, the second die 806 and wafer cap are shown in sectional view to show an example on-substrate device 904. As shown in FIG. 9, a surface 906 of the wafer cap 808 is spaced apart from the on-substrate device 904 by at least a DAM 907 (e.g., a fusible alloy or other DAM). In some examples (see, e.g., FIG. 4 or 5), a wall can also be provided to support the wafer cap 808 over the on-substrate device 904 and provide further spacing between the wafer cap 808 and surface of the second die 806. Additionally, in some examples, the second die 806 includes an isolation trench 908 around the on-substrate device 904.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/−10 percent of the stated value, or, if the value is zero, a reasonable range of values around zero. Modifications are possible in the described examples, and other implementations are possible, within the scope of the claims.

What is claimed is:

1. An apparatus, comprising:
a substrate having opposing first and second surfaces;
an on-substrate device on the first surface of the substrate;
a wafer cap on the first surface of the substrate over the on-substrate device; and
a peripheral ring layer of a fusible alloy configured to hermetically seal the wafer cap to the first surface of the substrate around the on-substrate device.

2. The apparatus of claim 1, wherein the wafer cap has opposing third and fourth surfaces, and the fourth surface of the wafer cap is joined to the first surface of the substrate, and the wafer cap further comprises:
a supporting layer of material on the fourth surface of the wafer cap, in which the supporting layer has a surface spaced apart from the second surface of the wafer cap by a peripheral edge of the supporting layer; and
a channel in the supporting layer spaced inwardly from the peripheral edge along a periphery of the wafer cap.

3. The apparatus of claim 2, wherein the supporting layer comprises a polyimide.

4. The apparatus of claim 2, wherein at least a portion of the fusible alloy resides in the channel.

5. The apparatus of claim 2, wherein the wafer cap further comprises:
a standoff ring in the channel extending outwardly from the second surface of the wafer cap beyond the surface of the supporting layer to terminate in a distal end of the standoff ring, the fusible alloy being interposed between the distal end of the standoff ring and the first surface of the substrate.

6. The apparatus of claim 1, wherein the wafer cap further comprises a standoff ring extending outwardly from the second surface of the wafer cap along a periphery thereof to terminate in a distal end of the standoff ring, the fusible alloy being interposed between the distal end of the standoff ring and the first surface of the substrate.

7. The apparatus of claim 1, wherein the substrate further comprises a peripheral layer of metal material on the first surface of the substrate spaced from and surrounding the on-substrate device, the fusible alloy being coextensive with and joined to the peripheral layer of metal material to hermetically seal the wafer cap around the on-substrate device.

8. The apparatus of claim 1, wherein the substrate is a die and the apparatus further comprises:
a leadframe having a die-attach surface area, the second surface of the die attached to the die-attach surface area of the leadframe; and
a mold compound encapsulating the die, the wafer cap and at least a portion of the leadframe.

9. The apparatus of claim 1, wherein the on-substrate device comprises a bulk acoustic wave device.

10. A method of making an apparatus, comprising:
providing a substrate that includes an on-substrate device on a first surface of the substrate;
placing a wafer cap on the first surface of the substrate over the on-substrate device, in which the wafer cap includes a continuous ring of a fusible alloy on a respective surface of the wafer cap, and the ring of the fusible alloy surrounds the on-substrate device; and
reflowing the fusible alloy to bond the respective surface of the wafer cap to the first surface of the substrate and, after cooling, seal the wafer cap around the on-substrate device.

11. The method of claim 10, wherein:
the substrate further comprises a ring-shaped layer of a metal material on the first surface of the substrate spaced from and surrounding the on-substrate device,
the ring of fusible alloy is coextensive with the layer of metal material, and
reflowing the fusible alloy includes forming an hermetic seal between the wafer cap and the substrate around the on-substrate device.

12. The method of claim 10, wherein the substrate is a first substrate, the wafer cap is a first wafer cap and, prior to placing the first wafer cap on the first substrate, the method comprises:
forming a plurality of instances of the continuous ring of the fusible alloy at respective locations distributed across a first surface of a second substrate; and
singulating wafer caps from the second substrate to provide at least the first wafer cap.

13. The method of claim 12, wherein:
adjacent pairs of instances of the continuous ring are spaced apart from each other by an area of on the first surface of the second substrate that includes a portion of a saw street that extends across the second substrate between respective adjacent pairs of the instances of the continuous ring, and
singulating wafer caps comprises sawing through respective saw streets of the second substrate with a mechanical saw to provide at least the first wafer cap.

14. The method of claim 12, wherein forming the plurality of instances of the ring of fusible alloy comprises:
forming a patterned layer of photoresist on the first surface of the second substrate having recesses extending though the patterned layer of photoresist to the first surface of the second substrate, in which the recesses are arranged and configured to be coterminous with the respective locations;
plating the fusible alloy in the recesses and on the first surface of the second substrate;
removing the patterned layer of photoresist from the first surface of the second substrate; and
reflowing the fusible alloy to form respective instances of the ring of fusible alloy on the first surface of the second substrate.

15. The method of claim 12, wherein prior to singulating wafer caps, the method comprises:
forming a supporting layer of a polymer material on the first surface of the second substrate, in which the supporting layer extends from the first surface of the second substrate to terminate in a surface thereof; and
forming respective channels in the supporting layer, each respective channel being arranged and configured to be coterminous with the respective locations.

16. The method of claim 15, wherein:
each of the plurality of instances of the ring of fusible alloy resides in one of the respective channels; or
the method further comprises:
forming a standoff ring in each respective channel, in which the standoff rings extend outwardly from the second surface of the second substrate beyond the surface of the supporting layer to terminate in a distal end of the standoff ring, and
wherein each of the plurality of instances of the ring of fusible alloy is formed on the distal end of a respective one of the standoff rings.

17. The method of claim 10, wherein the substrate is a die containing the on-substrate device, and the method further comprises:
attaching a second side of the die to a leadframe; and
encapsulating the die, the wafer cap and at least a portion of the leadframe within a mold compound.

18. The method of claim 10, wherein the on-substrate device comprises a bulk acoustic wave device.

19. A method, comprising:
forming a plurality of instances of a continuous ring of die attach material at respective locations distributed across a first surface of a silicon substrate, in which adjacent pairs of the instances of the continuous ring are spaced apart from each other by an area of on the first surface that includes a portion of a saw street that extends across the substrate between respective adjacent pairs of the instances of the continuous ring; and
sawing through respective saw streets of the substrate to singulate wafer caps from the substrate, in which each of the singulated wafer caps includes a respective instance of the continuous ring of die attach material on the first surface thereof.

20. The method of claim 19, wherein the die attach material comprises a fusible alloy and sawing through the saw streets comprises sawing through substrate with a mechanical saw to provide the singulated wafer caps.

21. The method of claim 20, wherein prior to sawing through the saw streets, the method comprises:
forming a plurality of supporting rings of a polymer material on the first surface of the substrate at the respective locations; and
forming respective channels in each supporting ring, in which each respective channel is arranged and configured to define the respective locations, such that each of the plurality of instances of the continuous ring of die attach material is coterminous with and formed within a respective channel.

22. The method of claim 20, further comprising:
providing a die that includes an on-substrate device on a first side of the die;
placing a respective one of the wafer caps on the first side of the die over the on-substrate device, such that the continuous ring of the fusible alloy thereof surrounds the on-substrate device on the first side of the die;
reflowing the fusible alloy to bond the respective one of the wafer caps to the first side of the die and, after cooling, seal the respective one of the wafer caps around the on-substrate device;
attaching a second side of the die to a leadframe; and
encapsulating the die, the respective one of the wafer caps and at least a portion of the leadframe within a mold compound.

23. A wafer cap produced according to the method of claim 20.
